(19) United States
(12) Patent Application Publication
(10) Pub. No.: US 2023/0045307 A1
(43) Pub. Date: Feb. 9, 2023

(54) REPLACEMENT LIQUID OF LIQUID FILLING BETWEEN RESIST PATTERNS, AND METHOD FOR PRODUCING RESIST PATTERNS USING THE SAME

(71) Applicant: Merch Patent GmbH, Darmstadt (DE)

(72) Inventors: Kazuma YAMAMOTO, Kakegawa-shi (JP); Takafumi KINUTA, Kakegawa-shi (JP); Tatsuro NAGAHARA, Kakegawa-shi (JP); Maki ISHII, Kakegawa-shi (JP)

(21) Appl. No.: 17/777,638

(22) PCT Filed: Nov. 16, 2020
(86) PCT No.: PCT/EP2020/082179

§ 371 Date: May 18, 2022

(30) Foreign Application Priority Data
Nov. 18, 2019 (JP) 2019-207844

(51) Int. Cl. G03F 7/42

(52) U.S. Cl. CPC G03F 7/425

(57) ABSTRACT

Problem: A replacement liquid of liquid filling between resist patterns and a method for producing resist patterns using the same. Means of solution: To provide a replacement liquid of liquid filling between resist patterns comprising a sulfonyl group-containing compound (A); a nitrogen-containing compound (B); and a solvent (C).

### BACKGROUND OF THE INVENTION

### Technical Field

The present invention relates to a replacement liquid of liquid filling between resist patterns and a method for producing resist patterns using the same. The present invention further relates to a method for producing a processed substrate and a method for producing a device.

### Background Art

In recent years, needs for high integration of LSI has been increasing, and refining of resist patterns is required. In order to respond to such needs, lithography processes using KrF excimer laser (248 nm), ArF excimer laser (193 nm), extreme ultraviolet (EUV; 13 nm) and X-ray of short wavelength, electron beam, etc. have been put to practical use. In order to respond to such refining of resist patterns, also for photosensitive resin compositions to be used as a resist during refining processing, those having high resolution are required. However, as refining progresses as described above, resist pattern collapse, increase of the number of defects, and deterioration of pattern roughness tend to occur.

The resist pattern collapse is considered to occur also when a negative pressure is generated between the patterns due to the surface tension of water when the patterns are washed with water (deionized water) after development. In order to improve the collapse of resist pattern, there is a means for cleaning with a rinse liquid containing a certain component instead of conventional water (for example, Patent Document 1). Further, in order to improve the resist surface roughness, there is a means for applying a composition containing a certain component to between resist patterns after drying (for example, Patent Document 2).

### PRIOR ART DOCUMENTS

### Patent Documents

[Patent document 1] WO 2018/095885
[Patent document 2] WO 2016/060116

### SUMMARY OF THE INVENTION

### Problems to be Solved by the Invention

The present inventors considered that there are one or more still need improvements. These include, for example, the followings:

Preventing resist pattern from being collapsed in fine resist patterns; reducing defects in fine resist patterns; suppressing surface energy variation of resist films; reducing the components derived from developer and remaining between resist pattern films; suppressing swelling of resist patterns; reducing the frequency of generation of water drops in the step of drying resist patterns; increasing hardness and/or elastic modulus of resist patterns; and suppressing the shape variation of resist patterns.

### Means for Solving the Problems

The replacement liquid of liquid filling between resist patterns according to the present invention comprises:

a sulfonyl group-containing compound (A);
a nitrogen-containing compound (B); and
a solvent (C),
wherein the sulfonyl group-containing compound (A) is represented by the formula (a):

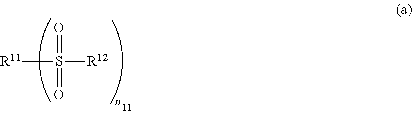

where

R¹¹ is C₁₋₂₀ alkyl, C₁₋₂₀ alkyl in which a part or all of hydrogen is substituted with halogen or —OH, C₆₋₁₀ aryl which is unsubstituted or substituted with R¹³, —OH or nitrogen, and H⁺ that is ionically bonded to nitrogen can be changed to NH₄⁺,

R¹² is —OH, C₁₋₁₅ alkyl, or C₁₋₁₅ alkyl in which a part or all of hydrogen is substituted with halogen,

R¹³ is C₁₋₅ alkyl, or C₁₋₅ alkyl in which a part or all of hydrogen is substituted with halogen,

the alkyl in R¹¹, R¹² or R¹³ can form a ring, and two or more of these can be bonded to each other to form a ring,

n₁₁=1, 2 or 3; and

wherein the solvent (C) comprises water.

The method for producing resist patterns comprises the following steps:

(1) applying a photosensitive resin composition on a substrate, with or without one or more intermediate layers, to form a photosensitive resin layer;
(2) exposing the photosensitive resin layer to radiation;
(3) applying a developer to the exposed photosensitive resin layer to form resist patterns;
(4) applying the above-mentioned replacement liquid of liquid filling between resist patterns to between the resist patterns to replace the liquid present between the resist patterns; and
(5) removing the replacement liquid of liquid filling between resist patterns.

The method for producing a processed substrate according to the present invention comprises the following steps:

producing resist patterns by the above-mentioned method; and
(6) processing is performed using the resist patterns as a mask.

The method for producing a device according to the present invention comprises the following step: producing the processed substrate by the above-mentioned method.

### Effects of the Invention

Using the replacement liquid of liquid filling between resist patterns according to the present invention, it is possible to expect one or more of the following effects.

It is possible to prevent resist pattern from being collapsed in fine resist patterns; to reduce defects in fine resist patterns; to suppress surface energy variation of resist films; to reduce the components derived from developer and remaining between resist pattern films; to suppress swelling of resist patterns; to reduce the frequency of generation of water drops in the step of drying resist patterns; to increase hardness and/or elastic modulus of resist patterns; and to suppress the shape variation of resist patterns.

### DETAILED DESCRIPTION OF THE INVENTION

### Mode for Carrying Out the Invention

Embodiments of the present invention are described below in detail.

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, the compound itself that generates a base). An aspect in which the compound is dissolved or dispersed in a solvent and added to the composition is also possible. As one embodiment of the present invention, it is preferable that such a solvent is contained in the composition according to the present invention as the solvent (C) or another component.

### <Replacement Liquid of Liquid Filling Between Resist Patterns>

The replacement liquid of liquid filling between resist patterns according to the present invention (hereinafter sometimes referred to as replacement liquid) comprises a sulfonyl group-containing compound (A), a nitrogen-containing compound (B), and a solvent (C).

Here, the replacement liquid of liquid filling between resist patterns is characterized by being applied to between the resist patterns to replace the liquid present between the resist patterns. That is, the replacement liquid of liquid filling between resist patterns according to the present invention is applied to between wet resist patterns after the development process, and this is different from the resist pattern processing liquid that is applied to between resist patterns after being dried after the development process.

### Sulfonyl Group-Containing Compound (A)

The sulfonyl group-containing compound (A) used in the present invention is represented by the formula (a):

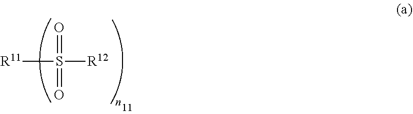

wherein

R¹¹ is C₁₋₂₀ alkyl, C₁₋₂₀ alkyl in which a part or all of hydrogen is substituted with halogen (preferably fluorine) or —OH, C₆₋₁₀ aryl which is unsubstituted or substituted with R¹³, —OH or nitrogen. Here, nitrogen means —NH₂ when n₁₁=1 and —NH— when n₁₁=2. H⁺ that is ionically bonded to nitrogen can be changed to NH₄⁺. For example, it is also accepted that when n₁₁=2, H⁺ of —NH— can be changed to NH₄⁺ to form an ammonium salt. In a preferred aspect of the present invention, H⁺ that is ionically bonded to nitrogen is not changed to NH₄⁺. Here, the above-mentioned C₁₋₂₀ alkyl shall mean a C₁₋₂₀, divalent or trivalent, saturated hydrocarbon group when n₁₁ is 2 or 3.

R¹² is —OH, C₁₋₁₅ alkyl, or C₁₋₁₅ alkyl in which a part or all of hydrogen is substituted with halogen.

R¹³ is C₁₋₅ alkyl, or C₁₋₅ alkyl in which a part or all of hydrogen is substituted with halogen.

The alkyl in R¹¹, R¹² or R¹³ can form a ring, and two or more of these can be bonded to each other to form a ring.

n₁₁=1, 2 or 3; preferably 1 or 2; more preferably 1. n₁₁=2 is also another preferred aspect.

Although not to be bound by theory, it is considered that, having a sulfonyl group (more preferably a sulfonic acid or sulfonylimide skeleton) makes it possible to remove the residual components of the developer (more preferably an alkaline aqueous solution, further preferably tetramethylammonium hydroxide (TMAH) aqueous solution) remaining between the resist patterns.

As one preferable embodiment, the formula (a) is represented by the formula (a-1):

R¹⁴—SO₃H (a-1)

wherein

R¹⁴ is C₁₋₂₀ alkyl, C₁₋₂₀ alkyl in which a part or all of hydrogen is substituted with fluorine or —OH, C₆₋₁₀ aryl which is unsubstituted or substituted with R¹³, or —OH, and

R¹³ is C₁₋₅ alkyl.

The formula (a-1) is preferably represented by the formula (a-1-1), (a-1-2) or (a-1-3):

R¹⁵—SO₃H (a-1-1)

wherein

R¹⁵ is —OH, C₁₋₉ alkyl, or C₁₋₉ alkyl in which a part or all of hydrogen is substituted with fluorine or —OH. R¹⁵ is preferably —OH, linear C₁₋₃ alkyl, hydroxymethyl, hydroxyethyl, or C₁₋₈ alkyl in which a part or all of hydrogen is substituted with fluorine; more preferably —OH, methyl, ethyl, hydroxymethyl, C₁₋₄ alkyl in which all of hydrogen is substituted with fluorine, or C₅₋₈ alkyl in which a part of hydrogen is substituted with fluorine.

Examples of these include sulfuric acid, methanesulfonic acid, ethanesulfonic acid, trifluoromethanesulfonic acid, hydroxymethanesulfonic acid, nonafluorobutanesulfonic acid and tridecafluorooctane-sulfonic acid.

CₘH₂ₘ₊₁SO₃H (a-1-2)

wherein

m is a number of 10 to 20. m is preferably a number of 11 to 19, more preferably a number of 12 to 18, and further preferably a number of 13 to 18.

Examples of these include decane sulfonic acid, 1-dodecane sulfonic acid and 1-tetradecane sulfonic acid. For example, an alkylsulfonic acid represented by (a-1-2) having 11 to 19 carbon atoms (m=11 to 19 in the above formula) is one suitable aspect as the sulfonyl group-containing compound (A) of the present invention.

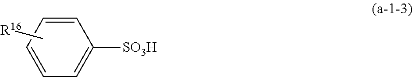

wherein

R¹⁶ is hydrogen or C₁₋₅ alkyl, preferably hydrogen, methyl or t-butyl, and further preferably hydrogen or methyl.

Examples of these include benzene sulphonic acid and toluene sulphonic acid.

As one of the preferred embodiments, the formula (a) is represented by the formula (a-2):

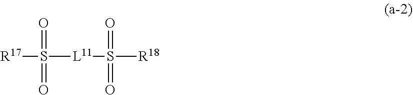

wherein

L¹¹ is C₁₋₅ alkylene, or —NH—; preferably C₁₋₃ alkylene or —NH—; more preferably —NH—. H⁺ that is ionically bonded to nitrogen can be changed to NH₄⁺. In a preferred aspect of the present invention, H⁺ that is ionically bonded to nitrogen is not changed to NH₄⁺.

R¹⁷ and R¹⁸ are each independently —OH, C₁₋₁₅ alkyl, or C₁₋₁₅ alkyl in which a part or all of hydrogen is substituted with fluorine; preferably —OH, or C₁₋₅ alkyl in which all of hydrogen is substituted with fluorine.

The alkyl in R¹⁷ and R¹⁸ can be bonded to each other to form a ring. Examples of these include ethanedisulfonic acid, bis(trifluoromethanesulfonyl)amide, bis(nonafluoro-butanesulfonyl)imide and cyclohexafluoropropane-1,3-bis(sulfonylamide).

For example, the below left compound is cyclohexafluoropropane-1,3-bis(sulfonylamide) and can be included in the formula (a-2). In this case, it can be read that L¹¹ is —NH—, R¹⁷ is fluoroethyl (C₂), R¹⁸ is fluoromethyl (C₁), and R¹⁷ and R¹⁸ are bonded to each other to form a ring. The below right compound is an ammonium salt obtained by changing H⁺ that is ionically bonded to nitrogen of the below left compound to NH₄⁺.

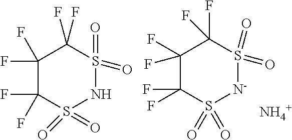 [SMILES: O=S1(=O)NS(=O)(=O)C(F)(F)C(F)(F)C1(F)F ; O=S1(=O)[N-]S(=O)(=O)C(F)(F)C(F)(F)C1(F)F ; [NH4+]]

The molecular weight of the sulfonyl group-containing compound (A) is preferably 90 to 600; more preferably 90 to 300; and further preferably 220 to 350.

The content of the sulfonyl group-containing compound (A) is preferably 0.01 to 10 mass %, more preferably 0.05 to 3 mass %, and further preferably 0.1 to 1 mass %, based on the total mass of the replacement liquid of liquid filling between resist patterns.

### Nitrogen-Containing Compound (B)

The replacement liquid according to the present invention comprises a nitrogen-containing compound (B). The nitrogen-containing compound (B) plays a role of controlling the acidity of the replacement liquid according to the present invention. Although not to be bound by theory, it is considered that when the nitrogen-containing compound (B) is not contained, deprotection of the resist is induced by the acidic component (for example, the sulfonyl group-containing compound (A) or the polymer (D)) and the pattern collapse can occur.

The nitrogen-containing compound (B) is a monoamine compound (B1), a diamine compound (B2), or a heteroaryl containing 1 to 3 nitrogen atoms (B3).

### Monoamine Compound (B1)

The monoamine compound (B1) is represented by the formula (b1):

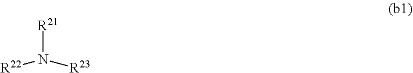

wherein

R²¹, R²² and R²³ are each independently H, C₁₋₅ alkyl, or C₁₋₅ alkanol; and

the alkyl in R²¹, R²² and R²³ can form a ring, two or more of these can be bonded to each other, and the —CH₂— moiety of the alkyl in R²¹, R²² and R²³ can be replaced with —O—.

In the present invention, ammonia (all of R²¹, R²² and R²³ are H) shall be included in the monoamine compound (B1). As the monoamine compound (B1), ammonia is also a preferred aspect.

Examples of the monoamine compound (B1) other than ammonia include the following compounds.

(i) primary amines, such as propylamine, butylamine, pentylamine, 2-methylbutylamine, 2-aminoethanol, 3-amino-1-propanol, aminoethoxy-ethanol, cyclohexylamine and cyclopentylamine,

(ii) secondary amines, such as diethylamine, dipropylamine, dibutylamine, dimethanolamine, diethanolamine, piperidine, morpholine and pyrrolidine; and

(iii) tertiary amines, such as triethylamine, tripropylamine, N-methyldiethylamine, trimethanolamine and triethanolamine.

### Diamine Compound (B2)

The diamine compound (B2) is represented by the formula (b2):

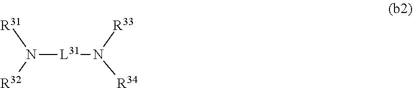

wherein

R³¹, R³², R³³ and R³⁴ are each independently H, C₁₋₅ alkyl, or C₁₋₅ alkanol,

the alkyl in R³¹, R³², R³³ and R³⁴ can form a ring, two or more of these can be bonded to each other, and the —CH₂— moiety of the alkyl in R³¹, R³², R³³ and R³⁴ can be replaced with —O—, and

L³¹ is C₁₋₅ alkylene, and the —CH₂— moiety of the alkylene can be replaced with —O—.

Examples of the diamine compound (B2) include:

ethylenediamine,
1,2-diaminopropane,
1,3-diaminopropane,
N,N,N′,N′-tetramethylethylenediamine,
N,N,N′,N′-tetraethylethylenediamine,
N,N,N′,N′-tetrapropylethylenediamine,
N,N,N′,N′-tetraisopropylethylenediamine,
N,N,N′,N′-tetrabutylethylenediamine,
N,N,N′,N′-tetraisobutylethylenediamine,
N,N,N′,N′-tetramethyl-1,2-propylenediamine,
N,N,N′,N′-tetraethyl-1,2-propylenediamine,
N,N,N′,N′-tetrapropyl-1,2-propylenediamine,
N,N,N′,N′-tetraisopropyl-1,2-propylenediamine,
N,N,N′,N′-tetramethyl-1,3-propylenediamine,
N,N,N′,N′-tetraethyl-1,3-propylenediamine,
N,N,N′,N′-tetrapropyl-1,3-propylenediamine,
N,N,N′,N′-tetraisopropyl-1,3-propylenediamine,
N,N,N′,N′-tetraisobutyl-1,3-propylenediamine,
N,N,N′,N′-tetramethyl-1,2-butylenediamine,
N,N,N′,N′-tetraethyl-1,2-butylenediamine,

### N,N-dimethylaminoethylamine,

### N,N-diethylaminoethylamine,

### N,N-dimethylaminopropylamine,

### N,N-diethylaminopropylamine,

### N-methylaminoethylamine,

### N-ethylaminoethylamine,

N-(2-aminoethylamino)ethanol,
piperazine, and
1,4-diazabicyclo[2.2.2]octane.

### Heteroaryl Containing 1 to 3 Nitrogen Atoms (B3)

The heteroaryl containing 1 to 3 nitrogen atoms is preferably a 5-membered ring or a 6-membered ring, and examples thereof include pyridine, imidazole and triazine. The number of nitrogen atoms contained is preferably 1 or 2, more preferably 1.

The content of the nitrogen-containing compound (B) is preferably 0.01 to 20 mass %; more preferably 0.01 to 5 mass %; further preferably 0.01 to 1 mass %; and further more preferably 0.1 to 1 mass %, based on the total mass of the replacement liquid of liquid filling between resist patterns.

The molecular weight of the nitrogen-containing compound (B) is preferably 17 to 170; more preferably 17 to 150; further preferably 17 to 120; and further more preferably 50 to 120.

### Solvent (C)

The replacement liquid according to the present invention comprises a solvent (C). The solvent (C) comprises water. The water is preferably deionized water. Since the solvent (C) is used for fine resist patterns, it is preferable that the solvent (C) has few impurities. The preferred solvent (C) contains impurities of 1 ppm or less; more preferably 100 ppb or less; and further preferably 10 ppb or less. Filtration of the liquid for use in a fine process is also a preferred aspect of the present invention.

The content of water based on the total mass of the solvent (C) is preferably 90 to 100 mass %; more preferably 98 to 100 mass %; further preferably 99 to 100 mass %; and further more preferably 99.9 to 100 mass %. In a preferred embodiment of the present invention, the solvent (C) consists essentially of water. However, an aspect in which an additive is dissolved and/or dispersed in a solvent other than water (for example, a surfactant) and contained in the replacement liquid of the present invention is accepted as a preferred aspect of the present invention.

As exemplified embodiments of the solvent (C) other than water, for example, cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol 1-monomethyl ether 2-acetate (PGMEA), propylene glycol monoethyl ether acetate, propylene glycol monopropyl ether acetate, γ-butyrolactone, ethyl lactate, or any mixture of any of these are preferable. These are preferable in terms of storage stability of the solution. These solvents can be also used as any mixture of any two or more.

The content of the solvent (C) is preferably 80 to 99.98 mass %, more preferably 90 to 99.5 mass %, and further preferably 95 to 99 mass %, based on the total mass of the replacement liquid of liquid filling between resist patterns.

Further, the water contained in the solvent (C) is preferably 80 to 99.94 mass %, more preferably 90 to 99.94 mass %, further preferably 95 to 99.94 mass %, based on the total mass of the replacement liquid of liquid filling between resist patterns.

The replacement liquid according to the present invention essentially comprises the above-mentioned components (A) to (C), but can comprise further compounds, if necessary. Details follows. The components other than (A) to (C) (in the case of a plurality, the sum thereof) in the entire composition are preferably 0 to 10 mass %, more preferably 0 to 5 mass %; and further preferably 0 to 3 mass %, based on the total mass of the replacement liquid. The aspect in which the replacement liquid according to the present invention contains no component other than (A) to (C) (0 mass %) is also a preferred aspect of the present invention.

### (D) Polymer

The replacement liquid according to the present invention can further comprise polymer (D).

The polymer (D) is preferably a water-soluble polymer from the viewpoint of affinity with the replacement liquid. Among them, polymer in which at least one group selected from the group consisting of sulfo (—SO₃H), carboxy (—COOH), hydroxy (—OH), carbonyl (—CO—) and salts thereof is contained in a repeating unit is preferred. Further preferably, the polymer (D) has sulfo (—SO₃H) and/or carboxy (—COOH) in the repeating unit.

Examples of the polymer (D) include polyacrylic acid, polymethacrylic acid, polymaleic acid, polyvinyl sulfonic acid, polystyrene sulfonic acid, fluorinated vinyl ether alkyl acid polymer, poly-2-acrylamido-2-methyl-1-propane sulfonic acid, polytrifluoromethylacrylic acid and salts thereof, and any copolymer of any of these.

Further, as the polymer (D), polyacrylamide or poly(trifluoromethyl)-4-penten-2-ol can also be used.

Including the polymer (D) makes it possible to improve the collapse prevention effect and the defect suppression effect.

The mass average molecular weight of the polymer (D) is preferably 1,000 to 100,000, more preferably 2,000 to 50,000, and particularly preferably 3,000 to 20,000. Here, the mass average molecular weight is a mass average molecular weight in terms of polystyrene, which can be measured by gel permeation chromatography based on polystyrene.

The content of the polymer (D) is preferably 0.1 to 20 mass %, more preferably 0.2 to 15 mass %, further preferably 0.5 to 10 mass %; and further more preferably 1 to 8 mass %, based on the total mass of the replacement liquid of liquid filling between resist patterns.

### Surfactant (E)

The replacement liquid according to the present invention can further comprise a surfactant (E). The surfactant (E) is a component different from (A) to (D).

The coating properties can be improved by including a surfactant.

In the present invention, the surfactant (E) means the compound itself having the above function. There is a case that the compound is dissolved or dispersed in a solvent to be contained in the composition (liquid), but such a solvent is preferably contained in the composition as the solvent (C) or other component. Hereinafter, the same applies to various additives that can be contained in the composition.

Examples of the surfactant that can be used in the present invention include anionic surfactants, cationic surfactants, and nonionic surfactants. More particularly, lauryl pyridinium chloride and lauryl methyl ammonium chloride, polyoxyethylene octyl ether, polyoxyethylene lauryl ether and polyoxyethylene acetylenic glycol ether, fluorine-containing surfactants (for example, Fluorad (trade name, 3M Japan Ltd.), Megafac (trade name, DIC Corporation), Surflon (trade name, AGC Inc.)), or organic siloxane surfactants (for example, KP341, trade name, Shin-Etsu Chemical Co., Ltd.) are included.

The content of the surfactant (E) is preferably 0.01 to 5 mass %, more preferably 0.03 to 1 mass %, based on the total mass of the replacement liquid according to the present invention. It is also a preferred aspect that no surfactant (E) is contained (0.0 mass %).

### Additive (F)

The replacement liquid used in the present invention can further comprise an additive (F). The additive (F) is a component different from (A) to (E). The additive (F) preferably comprises an acid, a base, a surfactant other than the surfactant (E), a germicide, an antimicrobial agent, a preservative, a fungicide, or any combination of any of these; and more preferably comprises an acid, a base, a germicide, an antimicrobial agent, a preservative, or a fungicide.

The content of the additive (F) is preferably 0.0005 to 20 mass %, more preferably 0.0005 to 1 mass %, based on the replacement liquid of liquid filling between resist patterns. It is also a preferred aspect that no additive (F) is contained (0.0 mass %).

### <Method for Producing Resist Patterns>

The method for producing resist patterns comprises the following steps:

(1) applying a photosensitive resin composition on a substrate, with or without one or more intermediate layers, to form a photosensitive resin layer;
(2) exposing the photosensitive resin layer to radiation;
(3) applying a developer to the exposed photosensitive resin layer to form resist patterns;
(4) applying the replacement liquid of liquid filling between resist patterns according to the present invention to between the resist patterns to replace the liquid present between the resist patterns; and
(5) removing the replacement liquid of liquid filling between resist patterns.

Although describing for clarity, the numbers in parentheses mean the order. For example, the step (4) is performed before the step (5).

Hereinafter, details are explained.

A photosensitive resin composition is applied above a substrate (for example, a silicon/silicon dioxide-coated substrate, a silicon nitride substrate, a silicon wafer substrate, a glass substrate, an ITO substrate, etc.) by an appropriate method. Here, in the present invention, the “above” includes the case where a layer is formed in contact with and above a substrate and the case where a layer is formed above a substrate with another layer in contact with the layer. For example, a planarization film or a resist underlayer can be formed in contact with and above a substrate, and the photosensitive resin composition can be applied in contact with and above it. The application method is not particularly limited, and examples thereof include a method using a spinner or a coater. After application, a photosensitive resin layer is formed optionally by heating. The heating is performed, for example, by a hot plate. The heating temperature is preferably 60 to 140° C., more preferably 90 to 110° C. The temperature here is a temperature of heating atmosphere, for example, that of a heating surface of a hot plate. The heating time is preferably 30 to 900 seconds, more preferably 60 to 300 seconds. The heating is performed preferably in the air or nitrogen gas atmosphere.

The thickness of the photosensitive resin layer is selected according to the purpose. It is also possible to make the thickness of the photosensitive resin layer thicker than 1 μm.

In the method for producing resist patterns according to the present invention, presence of film or layer other than the photosensitive resin layer is also accepted. Without direct contact of the substrate with the photosensitive resin layer, an intermediate layer can be interposed. The intermediate layer is referred to as a layer to be formed between a substrate and a photosensitive resin layer and is referred also to as underlayer film. As the underlayer film, a substrate modifying film, a planarization film, a bottom anti-reflecting coating (BARC), an inorganic hard mask intermediate layer (silicon oxide film, silicon nitride film and silicon nitrogen oxide film) can be referred. The intermediate layer can be composed of one layer or a plurality of layers. In addition, a top anti-reflective coating (TARC) can be formed on the photosensitive resin layer.

The photosensitive resin layer is exposed to radiation through a predetermined mask. When other layers (TARC layer etc.) are also included, they can be exposed together. The wavelength of the light used for exposure is not particularly limited, but it is preferable to perform exposure with light having a wavelength of 13.5 to 248 nm. In particular, KrF excimer laser (wavelength: 248 nm), ArF excimer laser (wavelength: 193 nm), extreme ultraviolet ray (wavelength: 13.5 nm) and the like can be used. These wavelengths allow a range of ±1%. After the exposure, post exposure bake (PEB) can be performed, if needed. The temperature for PEB is appropriately selected from 70 to 150° C.; preferably 80 to 120° C., and the heating time is appropriately selected from 30 to 300 seconds; preferably 30 to 120 seconds. The heating is preferably performed in the air or a nitrogen gas atmosphere.

Then, a developer is applied to the exposed photosensitive resin layer to form resist patterns. As the developing method, methods conventionally used for developing a photoresist, such as a paddle developing method, an immersion developing method, or a swinging immersion developing method, can be used. The preferred developing method is a paddle developing method. Further, as the developer, aqueous solutions containing an inorganic alkali, such as sodium hydroxide, potassium hydroxide, sodium carbonate and sodium silicate; an organic amine, such as ammonia, ethylamine, propylamine, diethylamine, diethylaminoethanol and triethylamine; a quaternary amine, such as TMAH; and the like, are used, and a 2.38 mass % (±1% is accepted) TMAH aqueous solution is preferably used. A surfactant or the like can be further added to the developer. The temperature of the developer is appropriately selected from generally 5 to 50° C.; preferably 25 to 40° C., and the development time is appropriately selected from generally 10 to 300 seconds; preferably 20 to 60 seconds.

In the state that the developer remains between resist patterns, the following step can be further comprised, if necessary:

(3.1) applying a cleaning liquid to the resist patterns to clean the resist patterns.
Here, as the cleaning liquid, those used in a known method can be used, and for example, water (deionized water) or a known rinse liquid can be used.

In the state that the developer or the above cleaning liquid remains between resist patterns, the replacement liquid according to the present invention is applied to between resist patterns to replace the liquid present between resist patterns.

When a developer is applied to the photosensitive resin layer to form resist patterns, components contained in the developer (for example, an alkaline component TMAH) sometimes remain between resist pattern films.

Although not to be bound by theory, the inventors thought as follows. The residual components derived from the developer are difficult to be removed with the above-mentioned cleaning liquid (water or rinse liquid). It is considered that, by applying the replacement liquid according to the present invention to between resist patterns, the residual components derived from the developer can be removed from between the resist pattern films by the sulfonyl group-containing compound that is contained in the replacement liquid according to the present invention. Functionally, absorption due to neutralizing energy can cause. That is, by the steps (4) and/or (5), the residual components derived from the developer are reduced from resist patterns.

It is considered that the residual components derived from the developer present between resist pattern films swell resist patterns, or the alkaline components are nonuniformly present between resist patterns, resulting in nonuniform surface energy in resist patterns. It is considered that when the resist pattern surface energy is nonuniform, this becomes trigger for generating water droplets in the pattern drying, which causes pattern collapse. It is considered that applying the replacement liquid according to the present invention makes the residual components derived from the developer reduced, the swelling of resist patterns suppressed, the hardness of resist patterns increased and additionally, the surface energy of the resist pattern uniformized, and as a result, the effect of suppressing the resist pattern collapse is attained. Therefore, it is more preferable not to dry resist patterns before applying the replacement liquid of the present invention. That is, it is preferable that resist patterns are not dried during the steps (3) to (4). As one of preferable embodiment of the present invention, the replacement liquid of the present invention can be a surface modifier of a resist coating, which comprises components of above mentioned (A), (B), (C) and so on. In here, though said resist coating is not limited to patterned one, it is more preferable that said resist coating is a patterned resist coating.

Incidentally, it is considered that the resist patterns obtained in the step (5) have higher hardness and/or elastic modulus than the resist patterns obtained by the steps up to (3).

As the stress to be applied to a resist wall during drying, the following is known.

The stress to be applied to a wall during drying can be indicated by the following formula, which is described as the formula (8) in Namatsu et al. Appl. Phys. Lett. 1995 (66) p 2655-2657:

σₘₐₓ=6γ cos θ/Dₓ(H/W)²

Further, a schematic diagram is shown in FIG. 5 of the same document.

σₘₐₓ: maximum stress to be applied to a resist,
γ: surface tension of a liquid
θ: contact angle,
D: distance between walls
H: height of wall, and
W: width of wall

The lengths of D, H and W can be measured by a known method (for example, SEM photograph).

As can be seen from the above formula, shorter D or shorter W causes more stress.

After applying the replacement liquid according to the present invention, this replacement liquid is removed. The removing method is not particularly limited, but is preferably performed by applying a cleaning liquid to between resist patterns. The preferred cleaning liquid is water or a rinse liquid as described above.

Finally, for example, by rotating the substrate at high speed, dried resist patterns are formed.

The method for applying the above cleaning liquid or the replacement liquid according to the present invention is not particularly limited, but the time for contacting with resist patterns, that is, the processing time is preferably 1 second or longer. Further, the processing temperature can also be any. The method of contact is also any, and for example, it can be performed by immersing the substrate in the liquid or dropping the liquid on the surface of the rotating substrate.

In the method for producing resist patterns of the present invention, one preferred aspect of the production method of the present invention comprises substituting the developer with water, substituting the water with the replacement liquid according to the present invention, substituting the replacement liquid with a cleaning liquid, and then drying the substrate by a high-speed rotation treatment.

In the resist patterns produced by the method of the present invention, generation of defects such as bridges can be suppressed, and resist pattern collapse can also be suppressed. In the present specification, the bridge is one in which an unintended structure exists in the trenches of resist patterns, and a kind of defect. This is because resist patterns (walls) are connected to each other, or foreign substances that must be cleaned off remain in the trenches. If the intended trench is filled up with the bridge, the intended circuit cannot be designed in the subsequent process such as etching. The mechanism by which the occurrence of defects such as bridges is suppressed when the replacement liquid according to the present invention is used has not been clarified, and it was unexpected to obtain such an effect.

### <Methods for Producing a Processed Substrate and a Device>

After producing resist patterns as described above, the processed substrate according to the present invention is formed by the following step:

(6) processing is performed using the resist patterns as a mask.

Using resist patterns produced by the producing method of the present invention as a mask, the intermediate layer and/or the substrate can be patterned. For the pattern formation, a known method such as etching (dry etching or wet etching) can be used. For example, the intermediate layer can be etched using the resist pattern as an etching mask, and the substrate can be etched using the obtained intermediate layer pattern as an etching mask to form a pattern on the substrate. Further, while etching the layer below the photoresist layer (for example, an intermediate layer) using the resist pattern as an etching mask, the substrate can be uninterruptedly etched. Wiring can be formed on the substrate utilizing the formed pattern.

These layers can be removed preferably by dry etching with O₂, CF₄, CHF₃, Cl₂ or BCl₃, and preferably, O₂ or CF₄ can be used.

Then, the device is formed, if necessary, by performing the following step:

(7) forming wiring on the processed substrate.

For these further processes, known methods can be applied. After formation of the device, if necessary, the substrate can be cut into chips, connected to a lead frame, and packaged with resin. A preferred example of the device is a semiconductor device.

The present invention is described below with reference to various examples. Incidentally, the aspects of the present invention are not limited to these examples.

### Examples 101 to 115, and Comparative Examples 102 and 103

In water (deionized water), ethanesulfonic acid as a sulfonyl group-containing compound (A) and ammonia as a nitrogen-containing compound (B) are added to make the contents thereof respectively 0.2 mass % and 0.5 mass % and dissolved. This is subjected to filtration (pore size=10 nm) to prepare the replacement liquid of Example 101.

In the same manner as in Example 101, except that the type and concentration of the sulfonyl group-containing compound (A), the nitrogen-containing compound (B) and the polymer (D) are respectively set as indicated in Table 1, the replacement liquids of Examples 101 to 115, and Comparative Examples 102 and 103 are prepared.

TABLE 1

| | | Composition | | | | | | | |
|---|---|---|---|---|---|---|---|---|---|
| | | (A) Sulfonyl | | | | | | | |
| | | group- | | (B) Nitrogen- | | | | Evaluation | |
| | | containing | | containing | | | | Collapse | Defect |
| | | compound | (mass %) | compound | (mass %) | (D) Polymer | (mass %) | prevention | supression |
| Example | 101 | A1 | 0.2 | B1 | 0.5 | — | — | A | B |
| | 102 | A2 | 0.2 | B1 | 0.5 | — | — | A | B |
| | 103 | A3 | 0.2 | B1 | 0.5 | — | — | A | B |
| | 104 | A4 | 0.2 | B1 | 0.5 | — | — | A | B |
| | 105 | A5 | 0.2 | B1 | 0.5 | — | — | A | B |
| | 106 | A6 | 0.2 | B1 | 0.5 | — | — | A | B |
| | 107 | A7 | 0.2 | B5 | 0.5 | — | — | A | B |
| | 108 | A2 | 0.2 | B2 | 0.5 | — | — | A | B |
| | 109 | A3 | 0.2 | B3 | 0.5 | — | — | A | B |
| | 110 | A1 | 0.2 | B1 | 0.5 | D1 | 2 | A | A |
| | 111 | A2 | 0.2 | B2 | 0.5 | D2 | 2 | A | A |
| | 112 | A3 | 0.2 | B3 | 0.5 | D3 | 2 | A | A |
| | 113 | A4 | 0.2 | B4 | 0.5 | D4 | 2 | A | A |
| | 114 | A5 | 0.2 | B1 | 0.5 | D1 | 2 | A | A |
| | 115 | A3 | 0.2 | B1 | 0.5 | D2 | 2 | A | A |
| Comparative | 101 | — | — | — | — | — | — | B | C |
| Example | 102 | A1 | 0.2 | — | — | D1 | 2 | B | B |
| | 103 | — | — | B1 | 0.5 | D1 | 2 | B | D |

In the table:
A1: ethanesulfonic acid,
A2: methanesulfonic acid,
A3: decanesulfonic acid,
A4: sulfuric acid,
A5: trifluoromethanesulfonic acid,
A6: bis(trifluoromethanesulfonyl)amide,
A7: a mixture of alkyl sulfonic acid compounds having 13 to 18 carbon atoms,
B1: ammonia,
B2: triethylamine,
B3: 2-aminoethanol,
B4: diethanolamine,
B5: N-(2-aminoethylamino) ethanol,
D1: polyacrylic acid represented by the following structural formula: 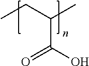
D2: polyvinylsulfonic acid represented by the following structural formula, 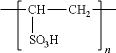
D3: fluorinated vinyl ether alkyl acid homopolymer represented by the following structural formula 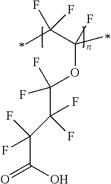
D4: poly(2-acrylamido-2-methyl-1-propanesulfonic acid)

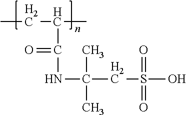

### <Evaluation of Collapse Prevention Effect>

A bottom anti-reflective coating-forming composition (AZ Kr-F17B, produced by Merck Performance Materials Ltd. (hereinafter referred to as MPM)) is applied on a silicon substrate by spin coating, and heating is performed on a hot plate at 180° C. for 60 seconds to obtain a bottom anti-reflective coating having a film thickness of 80 nm. A PHS-acrylate-based chemically amplified resist (DX6270P, produced by MPM) is applied on this and heating is performed on a hot plate at 120° C. for 90 seconds to obtain a resist film having a film thickness of 620 nm. This substrate is exposed using a KrF stepper (FPA3000 EX5, produced by Canon) through a mask (250 nm, line/space 1:1). At this time, the exposure amount is changed from 25 mJ/cm² to 40 mJ/cm² so that the line width to be obtained is changed. After that, post-exposure baking (PEB) is performed on a hot plate at 100° C. for 60 seconds, a 2.38 mass % TMAH aqueous solution of a developer is poured in, and this state is held for 60 seconds (paddle). With the developer being paddled, water is started to flow. While rotating the substrate, the developer is replaced with water, this treatment is stopped in the state of being paddled with water, and this state is left standing for 90 seconds. After that, the replacement liquid of Example 101 prepared above is poured into the state of being paddled with water, the water is replaced with the replacement liquid, the pouring of the replacement liquid is stopped in the state of being paddled with the replacement liquid, and this state is left standing for 30 seconds. Then, it is dried by a high-speed rotation treatment for 30 seconds, and water is further poured thereinto to clean for 30 seconds. Finally, after the substrate is dried by a high-speed rotation process, it is observed whether or not the resist pattern is collapsed, using a length measuring SEM CG4000 (produced by Hitachi High-Technologies).

The same procedure is performed using the replacement liquids of Examples 102 to 115, and Comparative Examples 102 and 103, respectively.

In Comparative Example 101, the developer is paddled in the same manner as in Example 101 described above, and then water is poured thereinto, cleaning is performed for 30 seconds, and the substrate is dried by a high-speed rotation treatment. That is, in Comparative Example 101, the treatment with the replacement liquid is not performed. At this time, if the line width becomes narrower than 188 nm, collapse of the resist pattern is confirmed.

The evaluation criteria are as follows. The obtained results are as shown in Table 1.

A: When the line width is 150 nm or more and less than 178 nm, collapse of the resist pattern is not confirmed.
B: When the line width is 178 nm or more and less than 188 nm, collapse of the resist pattern is confirmed.
C: When the line width is 188 nm or more and 220 nm or less, collapse of the resist pattern is confirmed.

### <Evaluation of Defect Suppression Effect>

A PHS-acrylate-based chemically amplified resist for EUV is applied on a silicon substrate by spin coating, and heating is performed on a hot plate at 110° C. for 60 seconds to obtain a resist film having a film thickness of 45 nm. After a 2.38 mass % TMAH aqueous solution of a developer is poured in, and this state is held for 30 seconds. With the developer being padded, water is started to flow. While rotating the substrate, the developer is replaced with water, this treatment is stopped in the state of being paddled with water for 90 seconds. After that, the replacement liquid of Example 101 prepared above is poured into the state of being paddled with water, the water is replaced with the replacement liquid, this treatment is stopped in the state paddled with the replacement liquid for 30 seconds. Then, it is dried by a high-speed rotation treatment for 30 seconds, and water is further poured thereinto to clean for 30 seconds. Finally, the substrate is dried by a high-speed rotation process.

The same procedure is performed using the replacement liquids of Examples 102 to 115, and Comparative Examples 102 and 103, respectively.

In Comparative Example 101, the developer is paddled in the same manner as in Example 101 described above, and then water is poured thereinto, cleaning is performed for 30 seconds, and the substrate is dried by a high-speed rotation treatment. That is, the treatment with the replacement liquid is not performed.

The respective number of defects is observed using a wafer surface inspection system LS9110 (produced by Hitachi High-Technologies) and evaluated as follows. The obtained results are as shown in Table 1.
A: The number of defects is less than 25% as compared with Comparative Example 101.
B: The number of defects is 25% or more and less than 50% as compared with Comparative Example 101.
C: The number of defects is 50% or more and less than 150% as compared with Comparative Example 101.
D: The number of defects is 150% or more as compared with Comparative Example 101.

### Examples 201 to 208

The replacement liquids of Examples 201 to 208 are prepared in the same manner as in Example 101, except that the type and concentration of the sulfonyl group-containing compound (A), the nitrogen-containing compound (B) and the polymer (D) are respectively set as indicated in Table 2.

TABLE 2

| | | Composition | | | | | | Evaluation |
|---|---|---|---|---|---|---|---|---|
| | | (A) Sulfonyl | | | | | | Limit |
| | | group- | | (B) Nitrogen- | | | | pettern |
| | | containing | | containing | | | | size |
| | | compound | (mass %) | compound | (mass %) | (D) Polymer | (mass %) | (nm) |
| Example | 201 | A1 | 0.2 | B1 | 0.5 | — | — | 15.3 |
| | 202 | A1 | 0.2 | B1 | 0.5 | D1 | 2 | 14.6 |
| | 203 | A3 | 0.2 | B1 | 0.5 | — | — | 15.0 |
| | 204 | A3 | 0.2 | B1 | 0.5 | D1 | 2 | 14.2 |
| | 205 | A6 | 0.2 | B1 | 0.5 | — | — | 15.0 |
| | 206 | A6 | 0.2 | B1 | 0.5 | D1 | 2 | 14.4 |
| | 207 | A7 | 0.2 | B1 | 0.5 | — | — | 14.5 |
| | 208 | A7 | 0.2 | B1 | 0.5 | D1 | 2 | 13.7 |
| Comparative | 201 | — | — | — | — | — | — | 17.0 |
| Example | | | | | | | | |

### <Evaluation 1 of Limit Pattern Size>

A silicon substrate is processed with hexamethyldisilazane (HMDS) at 90° C. for 30 seconds. A PHS-acrylate-based chemically amplified resist for EUV is applied on this by spin coating and heated on a hot plate at 110° C. for 60 seconds to obtain a resist film having a film thickness of 45 nm. This substrate is exposed through a mask (18 nm, line/space 1:1) using an EUV stepper (NXE: 3300B, produced by ASML). At this time, the exposure amount is changed so that the line width to be obtained is changed. After that, post-exposure baking (PEB) is performed on a hot plate at 100° C. for 60 seconds, a 2.38 mass % TMAH aqueous solution of a developer is poured in, and this state is held for 30 seconds (paddle). With the developer being paddled, water is started to flow. While rotating the substrate, the developer is replaced with water, this treatment is stopped in the state of being paddled with water, and this state is left standing for 90 seconds. After that, the replacement liquid of Example 201 is poured into the state of being paddled with water, the water is replaced with the replacement liquid, the pouring of the replacement liquid is stopped in the state of being paddled with the replacement liquid, and this state is left standing for 30 seconds. Then, it is dried by a high-speed rotation treatment for 30 seconds, a surfactant-containing rinse liquid (AZ SPC-708, MPM) is poured thereinto to clean for 30 seconds, and thereafter, the substrate is dried by a high-speed rotation process.

Using a length measuring SEM CG4000 (produced by Hitachi High-Technologies), line width and existence of pattern collapse of the formed resist pattern are observed. The minimum line size where pattern collapse is not confirmed is referred to as the limit pattern size.

Similarly, the limit pattern sizes are obtained using the replacement liquids of Examples 202 to 208, respectively.

Comparative Example 201 is the result of the same procedure as above except that the replacement liquid is not poured.

The processes are evaluated by the following methods. A resist film formed by each of the methods described below is referred to as Comparative Example 301. Samples obtained by treating the resist film of Comparative Example 301 respectively with the processes A to E are referred to as Comparative Example 302, Comparative Example 303, Example 301, Example 302 and Example 303.

### [Formation of Resist Film]

A silicon substrate is processed with HMDS at 90° C. for 30 seconds. A PHS-acrylate-based chemically amplified resist for EUV is applied on this by spin coating and heated on a hot plate at 110° C. for 60 seconds to obtain a resist film having a film thickness of 40 nm.

### [Process A]

After pouring a 2.38 mass % TMAH aqueous solution of a developer is poured into the substrate, this state is held for 30 seconds. Water is started to flow in the state that the developer is paddled on the substrate. While rotating the substrate, the developer is replaced with water, this treatment is stopped in the state of being paddled with water, and this state is left standing for 90 seconds. Then, after cleaning for 30 seconds while pouring water in, the substrate is dried by a high-speed rotation treatment.

### [Process B]

After pouring a 2.38 mass % TMAH aqueous solution of a developer is poured into the substrate, this state is held for 30 seconds. Water is started to flow in the state that the developer is paddled on the substrate. While rotating the substrate, the developer is replaced with water, this treatment is stopped in the state of being paddled with water, and this state is left standing for 90 seconds. Then, after cleaning for 30 seconds while pouring a surfactant-containing rinse liquid (AZ SPC-708, MPM) in, the substrate is dried by a high-speed rotation treatment.

### [Process C]

After pouring a 2.38 mass % TMAH aqueous solution of a developer is poured into the substrate, this state is held for 30 seconds. Water is started to flow in the state that the developer is paddled on the substrate. While rotating the substrate, the developer is replaced with water, this treatment is stopped in the state of being paddled with water, and this state is left standing for 90 seconds. Then, the replacement liquid of Example 109 is poured in, the water is replaced with the replacement liquid, and thereafter, the state of being paddled with the replacement liquid is left standing for 30 seconds. Then, it is subjected to a high-speed rotation treatment for 30 seconds, thereby drying the substrate. Then, after cleaning for 30 seconds while pouring water to the substrate, the substrate is dried by a high-speed rotation treatment.

### [Process D]

After pouring a 2.38 mass % TMAH aqueous solution of a developer is poured into the substrate, this state is held for 30 seconds. Water is started to flow in the state that the developer is paddled on the substrate. While rotating the substrate, the developer is replaced with water, this treatment is stopped in the state of being paddled with water, and this state is left standing for 90 seconds. Then, the replacement liquid of Example 109 is poured in, the water is replaced with the replacement liquid, and thereafter, the state of being paddled with the replacement liquid is left standing for 30 seconds. Then, it is subjected to a high-speed rotation treatment for 30 seconds, thereby drying the substrate. Then, after cleaning for 30 seconds while pouring a surfactant-containing rinse liquid (AZ SPC-708, MPM) to the substrate, the substrate is dried by a high-speed rotation treatment.

### [Process E]

After pouring a 2.38 mass % TMAH aqueous solution of a developer is poured into the substrate, this state is held for 30 seconds. Water is started to flow in the state that the developer is paddled on the substrate. While rotating the substrate, the developer is replaced with water, this treatment is stopped in the state of being paddled with water, and this state is left standing for 90 seconds. Then, the replacement liquid of Example 109 is poured in, the water is replaced with the replacement liquid, and thereafter, the state of being paddled with the replacement liquid is left standing for 30 seconds. Then, it is subjected to a high-speed rotation treatment for 30 seconds, thereby drying the substrate.

### <TMAH Intensity>

The resist film obtained by the above formation of resist film is referred to as Comparative Example 301.

Using a time-of-flight secondary ion mass spectrometry TOF-SIMS (TOF.SIMS5, ION-TOF), the TMAH residual amount is measured by argon sputtering from the surface until 2 nm depth of a resist film of Comparative Example 302 (resist film after performing the process A on the resist film of Comparative Example 301), and this TMAH intensity is set to 1.0 (reference). The residual TMAH amount is similarly measured for the resist film of Comparative Example 301 and the resist films which are those after respectively performing the processes B to E on the resist film of Comparative Example 301, and the TMAH intensity with respect to the reference is evaluated.

The obtained results are as shown in Table 3. It is confirmed that the amount of TMAH remaining in resist films is reduced using the replacement liquid according to the present invention.

TABLE 3

| | | | | Limit | | | Contact angle |
|---|---|---|---|---|---|---|---|
| | | | TMAH | pettern size | Defect | Contact angle | uniformity |
| | | | intensity | (nm) | reduction rate | (degree) | (3 sigma) |
| Comparative | 301 | Resist film only | 0.0 | — | — | 84.5 | 3.1 |
| Example | 302 | Process A | 1.0 | 19.0 | 0% | 78.0 | 6.0 |
| | 303 | Process B | 1.0 | 17.0 | 70% | — | — |
| Example | 301 | Process C | 0.5 | 17.1 | 75% | 74.4 | 3.0 |
| | 302 | Process D | 0.5 | 15.3 | 92% | — | — |
| | 303 | Process E | 0.6 | — | — | — | — |

### <Evaluation 2 of Limit Pattern Size>

A silicon substrate is processed with HMDS at 90° C. for 30 seconds. A PHS-acrylate-based chemically amplified resist for EUV is applied on this by spin coating and heated on a hot plate at 110° C. for 60 seconds to obtain a resist film having a film thickness of 45 nm. This substrate is exposed through a mask (18 nm, line/space 1:1) using an EUV stepper (NXE: 3300B, produced by ASML). At this time, the exposure amount is changed so that the line width to be obtained is changed. After that, post-exposure baking (PEB) is performed on a hot plate at 100° C. for 60 seconds. Then, the processes A to D are respectively performed (Comparative Example 302, Comparative Example 303, Example 301 and Example 302).

Using a length measuring SEM CG4000 (produced by Hitachi High-Technologies), line width and existence of pattern collapse of the formed resist pattern are observed. The minimum line size where pattern collapse is not confirmed is referred to as the limit pattern size. The obtained results are as shown in Table 3.

### <Evaluation of Defect Reduction Rate>

A resist film is obtained in the same manner as the procedure performed in the above evaluation 2 of limit pattern size, except that the exposure amount is not changed. The processes A to D are performed on the resist film to form resist patterns (Comparative Example 302, Comparative Example 303, Example 301 and Example 302). The number of defects on the formed resist pattern is measured using a defect inspection apparatus (UVision4, produced by Applied Materials). Based on the number of defects when the process A is performed, the defect reduction rate when the processes B to D are performed is calculated. It is shown that the higher numerical value of the defect reduction rate, the more the defects are suppressed. The obtained results are as shown in Table 3.

### <Evaluation of Contact Angle and Contact Angle Uniformity>

A silicon substrate is processed with HMDS at 90° C. for 30 seconds. A PHS-acrylate-based chemically amplified resist for EUV is applied on this by spin coating and heated on a hot plate at 110° C. for 60 seconds to obtain a resist film having a film thickness of 40 nm (no treatment, Comparative Example 301). A resist film obtained in the same manner is processed by the process A or process C (Comparative Example 302, Example 301). DIW is dropped on the upper surface of the resist film and the contact angle is measured. The same sample is measured at 100 points to obtain 3 sigma. The obtained results are as shown in Table 3. Although not to be bound by theory, it is considered that the TMAH solution treatment causes a deviation in the residual amount of TMAH on the film surface, and by treating it with the replacement liquid of the present invention as a surface modifier, uniformity can be restored.

1.-15. (canceled)

16. A replacement liquid of liquid filling between resist patterns comprising:
a sulfonyl group-containing compound (A);
a nitrogen-containing compound (B); and
a solvent (C),
wherein the sulfonyl group-containing compound (A) is represented by the formula (a): 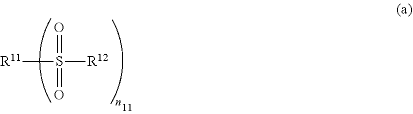
where
R¹¹ is C₁₋₂₀ alkyl, C₁₋₂₀ alkyl in which a part or all of hydrogen is substituted with halogen or —OH, C₆₋₁₀ aryl which is unsubstituted or substituted with R¹³, —OH or nitrogen, and H⁺ that is ionically bonded to nitrogen can be changed to NH₄⁺,
R¹² is —OH, C₁₋₁₅ alkyl, or C₁₋₁₅ alkyl in which a part or all of hydrogen is substituted with halogen,
R¹³ is C₁₋₅ alkyl, or C₁₋₅ alkyl in which a part or all of hydrogen is substituted with halogen,
the alkyl in R¹¹, R¹² or R¹³ can form a ring, and two or more of these can be bonded to each other to form a ring,
n₁₁=1, 2 or 3; and
wherein the solvent (C) comprises water.

17. The replacement liquid of liquid filling between resist patterns according to claim 16, wherein the nitrogen-containing compound (B) is a monoamine compound (B1); a diamine compound (B2); or a heteroaryl containing 1 to 3 nitrogen atoms (B3),
wherein the monoamine compound (B1) is represented by the formula (b1): 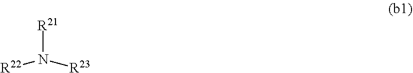
where
R²¹, R²² and R²³ are each independently H, C₁₋₅ alkyl, or C₁₋₅ alkanol; and
the alkyl in R²¹, R²² and R²³ can form a ring, two or more of these can be bonded to each other, and the —CH₂— moiety of the alkyl in R²¹, R²² and R²³ can be replaced with —O—; and
wherein the diamine compound (B2) is represented by the formula (b2): 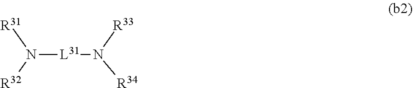
where
R³¹, R³², R³³ and R³⁴ are each independently H, C₁₋₅ alkyl, or C₁₋₅ alkanol,
the alkyl in R³¹, R³², R³³ and R³⁴ can form a ring, two or more of these can be bonded to each other, and the —CH₂— moiety of the alkyl in R³¹, R³², R³³ and R³⁴ can be replaced with —O—, and
L³¹ is C₁₋₅ alkylene, and the —CH₂— moiety of the alkylene can be replaced with —O—.

18. The replacement liquid of liquid filling between resist patterns according to claim 16, further comprising polymer (D).

19. The replacement liquid of liquid filling between resist patterns according to claim 16, wherein the content of the sulfonyl group-containing compound (A) is 0.01 to 10 mass %, based on the total mass of the replacement liquid of liquid filling between resist patterns;
preferably, the content of the nitrogen-containing compound (B) is 0.01 to 20 mass %, based on the total mass of the replacement liquid of liquid filling between resist patterns;
preferably, the content of the solvent (C) is 80 to 99.98 mass %, based on the total mass of the replacement liquid of liquid between filling between resist patterns;
preferably, water contained in the solvent (C) is 80 to 99.94 mass %, based on the total mass of the replacement liquid of liquid filling between resist patterns; or
preferably, the content of the polymer (D) is 0.1 to 20 mass %, based on the total mass of the replacement liquid of liquid between filling between resist patterns.

20. The replacement liquid of liquid filling between resist patterns according to claim 16, further comprising a surfactant (E).

21. The replacement liquid of liquid filling between resist patterns according to claim 20, further comprising an additive (F):
wherein the additive (F) comprises an acid, a base, a surfactant other than the surfactant (E), a germicide, an antimicrobial agent, a preservative, a fungicide, or any combination of any of these; or
the content of the additive (F) is 0.0005 to 20 mass %, based on the replacement liquid of liquid between filling between resist patterns.

22. The replacement liquid of liquid filling between resist patterns according to claim 16, wherein the replacement liquid of liquid filling between resist patterns is applied to between resist patterns to replace the liquid present in the resist patterns.

23. A method for producing resist patterns comprising the following steps:
(1) applying a photosensitive resin composition on a substrate, with or without one or more intermediate layers, to form a photosensitive resin layer;
(2) exposing the photosensitive resin layer to radiation;
(3) applying a developer to the exposed photosensitive resin layer to form resist patterns;
(4) applying the replacement liquid of liquid filling between resist patterns according to claim 16 to between the resist patterns to replace the liquid present between the resist patterns; and
(5) removing the replacement liquid of liquid filling between resist patterns.

24. The method for producing resist patterns according to claim 23, wherein the following step is further comprised:
(3.1) applying a cleaning liquid to the resist patterns to clean the resist patterns.

25. The method for producing resist patterns according to claim 23, wherein the resist patterns are not dried during the steps (3) to (4).

26. The method for producing resist patterns according to claim 23, wherein the removal of the replacement liquid of liquid filling between resist patterns in the step (5) is performed by applying a cleaning liquid to between the resist patterns.

27. The method for producing resist patterns according to claim 23, wherein residual components derived from the developer are reduced from the resist patterns by the steps (4) and (5): and the resist patterns obtained in the step (5) have higher hardness and/or elastic modulus than the resist patterns obtained by the steps up to (3).

28. The method for producing resist patterns according to claim 23, wherein residual components derived from the developer are reduced from the resist patterns by the steps (4) and (5).

29. A method for producing a processed substrate comprising the following steps:
producing resist patterns by the method according to claim 23; and
(6) processing is performed using the resist patterns as a mask.

30. A method for producing a device comprising the following step:
producing the processed substrate by the method according to claim 29.

31. The method for producing a device according to claim 30, wherein the following step is further comprised:
(7) forming wiring on the processed substrate.
